(19) United States
(12) Patent Application Publication
(10) Pub. No.: US 2013/0313671 A1
(43) Pub. Date: Nov. 28, 2013

(54) SUBSTRATE FOR A PHOTOVOLTAIC CELL

(71) Applicants: Octavio Cintora, Taverny (FR); Dominique Sachot, Ozoir La Ferriere (FR)

(72) Inventors: Octavio Cintora, Taverny (FR); Dominique Sachot, Ozoir La Ferriere (FR)

(73) Assignee: SAINT-GOBAIN GLASS FRANCE, Courbevoie (FR)

(21) Appl. No.: 13/984,859

(22) PCT Filed: Mar. 14, 2012
(86) PCT No.: PCT/FR2012/050528

§ 371 Date: Aug. 12, 2013

(30) Foreign Application Priority Data
Mar. 15, 2011 (FR) 1152093

(51) Int. Cl. H01L 31/0216

(52) U.S. Cl. CPC H01L 31/0216
USPC 257/432

(57) ABSTRACT

The subject of the invention is a substrate for photovoltaic cell comprising at least one sheet of float glass provided on a face of at least one electrode, characterized in that said glass has a chemical composition comprising the following constituents, in a weight content that varies within the limits defined below:

| | |
|---|---|
| SiO₂ | 60-70% |
| Al₂O₃ | 7-11% |
| MgO | 1-5% |
| CaO | 6-10% |
| Na₂O | 10-16% |
| K₂O | 0-4%. |

The invention relates to the field of substrates for photovoltaic cells. It relates more specifically to substrates for photovoltaic cells comprising at least one sheet of float glass provided on a face with at least one electrode.

The use of a thin-film photovoltaic material, typically made of CdTe or Cu(In, Ga) Se₂ (CIGS), makes it possible to replace expensive silicon substrates with substrates comprising sheets of glass. The material having photovoltaic properties, and generally the electrode, are deposited as a thin film by deposition processes of the evaporation, sputtering, chemical vapour deposition (CVD) or else sublimation (CSS) type onto the glass sheet. The latter must generally be heated to high temperature, either during the deposition, or after the deposition (annealing treatment, selenization treatment, etc.), and is therefore subjected to temperatures of the order of 500° C. or more. These treatments make it possible, for example, to improve the crystallinity of the layers and therefore their electron conduction or photovoltaic properties.

The high temperatures have, however, the drawback of giving rise to a deformation of the glass sheet when it is made of standard soda-lime-silica glass.

Glasses of higher heat resistance have been proposed, but they have a high production cost, due for example to the use of expensive raw materials (barium or strontium carriers for example), or particularly high melting points. In addition, some of these glasses lend themselves poorly to the forming of the glass by the float process.

The objective of the invention is to overcome these drawbacks, by proposing a glass composition that has an improved heat resistance rendering it compatible with the processes used during the manufacture of cells based on thin-film photovoltaic materials, particularly made of CdTe or Cu(In, Ga)Se₂ (GIGS), and additionally making it possible to produce a glass by the float process and under very favourable economic conditions.

For this purpose, one subject of the invention is a substrate for photovoltaic cell comprising at least one sheet of float glass provided on a face with at least one electrode, characterized in that said glass has a chemical composition comprising the following constituents, in a weight content that varies within the limits defined below:

| | |
|---|---|
| SiO₂ | 60-70% |
| Al₂O₃ | 7-12% |
| MgO | 0-5% |
| CaO | 6-10% |
| Na₂O | 10-16% |
| K₂O | 0-6%. |

These compositions surprisingly make it possible to impart high heat resistances to the glass substrates, characterized in particular by lower annealing temperatures at least 30° C. higher than those of standard glass.

The sum of the weight contents of SiO₂, Al₂O₃, CaO, MgO, Na₂O, K₂O is preferably at least 95%, in particular 98%. The content of SrO, BaO, B₂O₃ and/or ZrO₂ is advantageously zero in order not to penalize the cost of the glass sheet. The content of antimony oxides and arsenic oxides is also advantageously zero as these oxides are not compatible with the float process. The other constituents of the composition may be impurities originating from the raw materials (especially iron oxide) or due to the degradation of the refractory materials of the melting furnace or of the refining agents (especially SO₃).

Silica (SiO₂) is the main former element of the glass. At excessively low contents, the hydrolytic resistance of the glass, especially in a basic medium, would be too reduced. On the other hand, contents above 70% would lead to a highly prejudicial increase in the viscosity of the glass. The SiO₂ content is preferably at most 66%, especially 65.5% and even 65% and/or at least 61%, especially 62%, even 62.5% or 63%.

Alumina (Al₂O₃) makes it possible to increase the hydrolytic resistance of the glass and to reduce its refractive index, the latter advantage being particularly significant when the substrate is intended to constitute the front face substrate of the photovoltaic cell. The Al₂O₃ content is preferably at most 11.5%, especially 11%, even 10% and/or at least 8%, especially 8.5% or 9%.

The addition of lime (CaO) has the advantage of decreasing the high-temperature viscosity of the glass, and therefore facilitating the melting and refining thereof, while increasing the lower annealing temperature, and therefore the thermal stability. The increase in the liquidus temperature and in the refractive index that can be attributed to this oxide however result in the content thereof being limited. The content of CaO is preferably at most 9.5%, especially 9% and/or at least 7%, especially 7.5% or 8%. Magnesia (MgO) is useful for improving the chemical durability of the glass and reducing its viscosity. High contents result however in the risks of devitrification being intensified. The MgO content is preferably at most 5%, especially 4.5% or 4% and/or at least 3%.

Soda (Na₂O) is useful for reducing the high-temperature viscosity and the liquidus temperature. Contents that are too high result however in the hydrolytic resistance of the glass and its thermal stability being degraded, while increasing the cost. The Na₂O content is preferably at most 15%, especially 14.5%, even 14% and/or at least 11%, especially 12%, even 12.5% or 13%. Potash (K₂O) has the same advantages and drawbacks. The content thereof is preferably at most 4%, especially 3%. It may be zero in certain embodiments.

Particularly preferred compositions comprise the following constituents, in a weight content that varies within the limits defined below:

| | |
|---|---|
| SiO₂ | 61-66% |
| Al₂O₃ | 8-10% |
| MgO | 3-5% |
| CaO | 7-9% |
| Na₂O | 11-15% |
| K₂O | 0-4%. |

The glass may be melted in continuous furnaces, heated with the aid of electrodes and/or with the aid of overhead and/or submerged burners and/or burners positioned in the furnace crown so that the flame impacts the batch materials or the glass bath. The batch materials are generally pulverulent and comprise natural materials (sand, feldspars, limestone, dolomite, nepheline syenite, etc.) or synthetic materials (sodium carbonate or potassium carbonate, sodium sulphate, etc.). The batch materials are loaded into the furnace then undergo melting reactions in the physical sense of the term and various chemical reactions that lead to a glass bath being obtained. The molten glass is then conveyed to a forming step during which the glass sheet will take up its shape. The forming is carried out in a known manner by the float process, that is to say by pouring molten glass (having a viscosity of the order of 3000 poise) onto a bath of molten tin. The strip of glass obtained is then carefully annealed in order to eliminate all thermal stresses within it, before being cut to the desired dimensions. The thickness of the glass sheet is typically between 2 and 6 mm, especially between 2.5 and 4 mm.

The electrode is preferably in the form of a thin film deposited on the substrate (generally over the whole of one face of the substrate), directly in contact with the substrate or in contact with at least one sublayer. It may be a transparent and electrically conductive thin film, for example based on (fluorine-doped or antimony-doped) tin oxide, on (aluminium-doped or gallium-doped) zinc oxide, or based on indium tin oxide (ITO). It may also be a thin metallic layer, for example made of molybdenum. The transparent layers are generally used when the substrate is intended to form the front face substrate of the photovoltaic cell, as explained in further detail in the remainder of the text. The expression “front face” is understood to mean the face that the solar radiation passes through first.

The electrode, in thin-film form, may be deposited on the substrate by various deposition processes, such as chemical vapour deposition (CVD) or deposition by sputtering, especially when enhanced by a magnetic field (magnetron sputtering process). In the CVD process, halide or organometallic precursors are vaporized and transported by a carrier gas to the surface of the hot glass, where they decompose under the effect of the heat to form the thin film. The advantage of the CVD process is that it is possible to use it within the process for forming the glass sheet via the float process. It is thus possible to deposit the layer at the moment when the glass sheet is on the tin bath, at the outlet of the tin bath, or else in the lehr, that is to say at the moment when the glass sheet is annealed in order to eliminate the mechanical stresses. The CVD process is particularly suitable for the deposition of layers of fluorine-doped or antimony-doped tin oxide. The sputtering process will itself preferably be used for the deposition of layers of molybdenum, of doped zinc oxide or else of ITO.

Another subject of the invention is a semiconductor device comprising at least one substrate according to the invention and at least one thin film of a material having photovoltaic properties deposited on said at least one substrate.

The material having photovoltaic properties is preferably chosen from compounds of CdTe and Cu(In,Ga)Se₂ (CIGS) type. The term “(In,Ga)” is understood to mean that the material may comprise In and/or Ga, in all possible content combinations: In_{1-31 x}Gaₓ, it being possible for x to take any value from 0 to 1. In particular, x may be zero (material of CIS type). The material having photovoltaic properties may also be made of amorphous or polycrystalline silicon.

The photovoltaic material is deposited on the semiconductor device, on top of the electrode, and generally in contact with the latter. Various deposition techniques are possible, among which mention may be made, as examples, of evaporation, sputtering, chemical vapour deposition (CVD), electrolytic depositions or else sublimation (CSS). By way of example, mention may be made, in the case of layers of CIGS type, of the processes of sputtering or of electrolytic deposition (followed by a step of selenization) or co-evaporation.

An additional electrode may be deposited on (and especially in contact with) the layer of photovoltaic material. It may be a transparent and electrically conductive thin film, for example based on (fluorine-doped or antimony-doped) tin oxide, (aluminium-doped or gallium-doped) zinc oxide, or based on indium tin oxide (ITO). It may also be a metallic layer, for example made of gold or made of an alloy of nickel and aluminium. Transparent layers are generally used when the substrate is intended to form the back face substrate of the photovoltaic cell, as explained in greater detail in the remainder of the text. Buffer layers may also be inserted between the layer of photovoltaic material and the additional electrode. In the case of materials of CIGS type, it may be, for example, a layer of CdS.

Another subject of the invention is a photovoltaic cell comprising a semiconductor device according to the invention. A final subject of the invention is a photovoltaic module comprising a plurality of photovoltaic cells according to the invention.

Depending on the technology used, the substrate according to the invention may be the front face or back face substrate of the photovoltaic cell. By way of example, in the case of photovoltaic materials based on

CIGS, the CIGS layer is generally deposited on the back face substrate (provided with its electrode, typically made of molybdenum). It is therefore the back face substrate that then has a sheet of glass having the advantageous chemical composition described previously. In the case of CdTe technology on the other hand, the photovoltaic material is often deposited on the front face substrate, so that the aforementioned chemical composition is used for the glass sheet of the front face substrate.

The photovoltaic cell is formed by bringing together the front face and rear face substrates, for example by means of a lamination interlayer made of a thermosetting plastic, for example made of PVB, PU or EVA.

According to a first embodiment, the photovoltaic cell according to the invention comprises, as front face substrate, the substrate according to the invention, the chemical composition of the glass sheet of said substrate additionally comprising iron oxide in a weight content of at most 0.02%, in particular 0.015%. In this case, it is indeed important that the optical transmission of the glass be as high as possible. The sheet of glass preferably does not comprise any agent that absorbs visible or infrared radiation (especially for a wavelength between 380 and 1000 nm) other than the iron oxide (the presence of which is inevitable). In particular, the composition of the glass preferably does not contain agents chosen from the following agents, or any of the following agents: transition element oxides such as CoO, CuO, Cr₂O₃, MnO₂, rare-earth oxides such as CeO₂, La₂O₃, Nd₂O₃, or else colouring agents in the elemental state such as Se, Ag, Cu, Au. These agents very often have a very powerful undesirable colouring effect, which is manifested at very low contents, sometimes of around a few ppm or less (1 ppm=0.0001%). Still in order to maximize the optical transmission of the glass, the redox (defined as the ratio between the content of ferrous iron expressed in the form FeO and the total content of iron expressed in the form Fe₂O₃) is preferably at most 0.2, in particular 0.1. The glass sheet is preferably such that its energy transmission (T_{F}) calculated according to the standard ISO 9050:2003 is greater than or equal to 90%, in particular 90.5%, or 91% and even 91.5%, for a thickness of 3.2 mm. The front face substrate may be provided, on the face opposite that bearing the electrode, with an antireflection coating, for example made of porous silica or comprising a multilayer of thin films alternating between high and low refractive index layers. Within the context of this embodiment, use is typically made of a substrate according to the invention provided with an electrode made of ITO and/or made of doped SnO₂, a photovoltaic material made of CdTe, an additional electrode made of gold or made of an alloy of nickel and aluminium. The back face substrate is preferably made of standard soda-lime-silica glass.

According to a second embodiment, the photovoltaic cell according to the invention comprises, as back face substrate, the substrate according to the invention, the chemical composition of the glass sheet of said substrate additionally comprising iron oxide in a weight content of at least 0.05%, in particular within a range extending from 0.08 to 2%, in particular from 0.08 to 0.2%. In the context of this embodiment, use is typically made of a substrate according to the invention provided with an electrode made of molybdenum, a photovoltaic material made of CIGS, an additional electrode made of doped ZnO. High contents of iron oxide (from 0.5 to 2%) may in this case correct the aesthetic appearance due to the presence of molybdenum. The front face substrate is preferably made of extra-clear glass, of standard soda-lime-silica composition.

The present invention will be better understood on reading the detailed description below of non-limiting exemplary embodiments.

Table 1 below illustrates certain compositions according to the invention (Examples 1 to 6) and also a standard composition (Comparative Example C1).

Besides the chemical composition by weight, the table indicates the following physical properties:
the lower annealing temperature, referred to as S and expressed in ° C.,
the temperature at which the glass has a viscosity of 100 poise, referred to as T2 and expressed in ° C.,
the temperature at which the glass has a viscosity of 3162 poise, referred to as T3.5 and expressed in ° C.,
the forming margin, referred to as ΔT and expressed in ° C., corresponding to the difference between the temperature T3.5 and the liquidus temperature.

TABLE 1

| | C1 | 1 | 2 | 3 | 4 | 5 | 6 |
|---|---|---|---|---|---|---|---|
| SiO₂ | 71.8 | 63.2 | 65.1 | 62.4 | 63.8 | 63.5 | 61.5 |
| Al₂O₃ | 0.6 | 9.9 | 7.8 | 9.6 | 8.6 | 9.7 | 11.2 |
| CaO | 9.5 | 7.1 | 8.4 | 8.3 | 8.5 | 8.2 | 8.7 |
| MgO | 4.0 | 4.3 | 4.1 | 4.0 | 3.6 | 3.4 | 0.6 |
| Na₂O | 13.7 | 12.3 | 14.4 | 13.8 | 13.6 | 15.0 | 12.6 |
| K₂O | 0 | 3.1 | 0 | 1.7 | 1.7 | 0 | 5.2 |
| SO₃ | 0.28 | 0.26 | 0.29 | 0.29 | 0.29 | 0.29 | 0.27 |
| S (° C.) | 510 | 542 | 538 | 539 | 537 | 542 | 535 |
| T2 (° C.) | 1421 | 1498 | 1470 | 1470 | 1483 | 1477 | 1488 |
| T3.5 (° C.) | 1093 | 1175 | 1139 | 1145 | 1150 | 1149 | 1161 |
| ΔT (° C.) | 78 | 55 | 49 | 45 | 60 | 59 | 41 |

The compositions make it possible to obtain glasses having lower annealing temperatures of around 30° C. higher than that of standard glass. The result of this is a better mechanical behaviour, and glass sheets that are less likely to deform during the steps of manufacturing solar cells.

These glass compositions can be produced by the float process under good conditions, as attested to by the positive forming margins.

1. A substrate comprising:
at least one electrode; and
at least one sheet of a float glass provided on a face with the at least one electrode,
wherein said float glass comprises, by weight percent based on a total weight of the float glass:

| | |
|---|---|
| SiO₂ | 60-70%; |
| Al₂O₃ | 7-12%; |
| MgO | 0-5%; |
| CaO | 6-10%; |
| Na₂O | 10-16%; and |
| K₂O | 0-6%. |

2. The substrate of claim 1, wherein the sum of the weight contents of SiO₂, Al₂O₃, CaO, MgO, Na₂O, and K₂O in the float glass is at least 95%.

3. The substrate of claim 1, wherein the content of SiO₂ in the float glass is at least 61% and at most 66%.

4. The substrate of claim 1, wherein the content of Al₂O₃ in the float glass is at least 8% and at most 10%.

5. The substrate of claim 1, wherein the content of CaO in the float glass is at least 7% and at most 9%.

6. The substrate of claim 1, wherein the content of Na₂O in the float glass is at least 11% and at most 15%.

7. The substrate of claim 1, wherein the float glass comprises, by weight percent based on a total weight of the float glass:

| | |
|---|---|
| SiO₂ | 61-66%; |
| Al₂O₃ | 8-10%; |
| MgO | 3-5%; |
| CaO | 7-9%; |
| Na₂O | 11-15%; and |
| K₂O | 0-4%. |

8. The substrate of claim 1, wherein the electrode is a transparent and electrically conductive thin film comprising fluorine-doped tin oxide, antimony-doped tin oxide, aluminium-doped zinc oxide, gallium-doped zinc oxide, or indium tin oxide, or a thin film comprising molybdenum.

9. A semiconductor device, comprising: at least one substrate of claim 1; and
at least one thin film comprising a material having photovoltaic properties deposited on said at least one substrate.

10. The semiconductor device of claim 9, wherein the material having photovoltaic properties is selected from compounds of CdTe and Cu(In,Ga)Se₂ type.

11. A photovoltaic cell, comprising a semiconductor device of claim 9.

12. The photovoltaic cell of claim 11, comprising the substrate as a front face substrate, wherein the chemical composition of the float glass of said substrate further comprises iron oxide in a weight content of at most 0.02%, based on a total weight of the float glass.

13. The photovoltaic cell of claim 11, comprising the substrate as a back face substrate, wherein the chemical composition of the float glass of said substrate further comprises iron oxide in a weight content of at least 0.05%, based on a total weight of the float glass.

14. The photovoltaic cell of claim 13, wherein the material having photovoltaic properties is a compound of Cu(In,Ga)Se₂ type, and the electrode is a thin film made of molybdenum.

15. A photovoltaic module comprising a plurality of photovoltaic cells according to claim 11.

16. The substrate of claim 1, wherein the sum of the weight contents of SiO₂, Al₂O₃, CaO, MgO, Na₂O, and K₂O in the float glass is at least 98%.

17. The photovoltaic cell of claim 12, wherein the content of iron oxide in the float glass sheet is at most 0.015%.

18. The photovoltaic cell of claim 13, wherein the content of iron oxide in the float glass is from 0.08 to 2%.
